(19) United States
(12) Patent Application Publication
(10) Pub. No.: US 2024/0363454 A1
(43) Pub. Date: Oct. 31, 2024

(54) CIRCUIT PROBING PAD DESIGN IN SCRIBE LINE STRUCTURE AND METHOD FOR FABRICATING A SEMICONDUCTOR CHIP

(71) Applicant: NANYA TECHNOLOGY CORPORATION, New Taipei City (TW)

(72) Inventor: WU-DER YANG, TAOYUAN CITY (TW)

(21) Appl. No.: 18/239,231

(22) Filed: Aug. 29, 2023

Related U.S. Application Data
(62) Division of application No. 18/140,085, filed on Apr. 27, 2023.

(51) Int. Cl. H01L 21/66; G01R 31/28; H01L 21/78; H01L 23/00

(52) U.S. Cl. CPC H01L 22/32; G01R 31/2884; H01L 21/78; H01L 24/05; H01L 2224/05553

(57) ABSTRACT

A scribe line structure is provided. The scribe line structure includes a die region, a scribe line region, and one or more circuit probing pads. The die region is disposed on a semiconductor wafer. The scribe line region surrounds the die region. The one or more circuit probing pads are disposed on a first top surface of the die region and a second top surface of the scribe line region.

### CROSS-REFERENCE TO RELATED APPLICATION

This application is a divisional application of U.S. Non-Provisional application Ser. No. 18/140,085 filed Apr. 27, 2023, which is incorporated herein by reference in its entirety.

### TECHNICAL FIELD

The present disclosure relates to a semiconductor device, and more particularly, to a scribe line structure, a semiconductor device, and a method for fabricating a semiconductor chip.

### DISCUSSION OF THE BACKGROUND

When designing an LPDDR4 (Low Power Double Data Rate 4) memory chip, circuit probing pads and bonding pads may be located near an edge of the memory chip to improve high-speed electrical characteristics.

The area of a 2 Gb DDR4 DRAM chip is approximately 2 mm×4 mm using 18 nm technology, and there may be hundreds or thousands of the same memory chips on a semiconductor wafer. However, there could be many probing pads and bonding pads on each of the memory chip, and the area occupied by these probing pads and bonding pads within the total area of a memory chip can be considerable, resulting in higher cost and larger size of the memory chip.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a scribe line structure. The scribe line structure includes a die region, a scribe line region, and one or more circuit probing pads. The die region is disposed on a semiconductor wafer. The scribe line region surrounds the die region. The one or more circuit probing pads are disposed on a first top surface of the die region and a second top surface of the scribe line region.

Another aspect of the present disclosure provides a semiconductor device, which includes a plurality of die regions, a scribe line region, and a plurality of circuit probing pads. The plurality of die regions are disposed on a semiconductor wafer. The scribe line region is disposed between the plurality of die regions. The plurality of circuit probing pads are disposed on a first top surface of each die region and a second top surface of the scribe line region.

Yet another aspect of the present disclosure provides a method for fabricating a semiconductor chip. The method includes the following steps: fabricating a die region on a semiconductor wafer, wherein the die region is surrounded by a scribe line region; and forming a circuit probing pad on a first top surface of the die region and a second top surface of the scribe line region.

The foregoing outlines rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a top view of a semiconductor wafer 1 in accordance with some embodiments of the present disclosure.

FIG. 2A is an enlarged top view of a region 120 in accordance with the embodiment of FIG. 1.

FIG. 2B is an enlarged view of a scribe line structure 200 in FIG. 2A.

FIGS. 2C-2D are cross-sectional views of the semiconductor wafer 1 along line AA′ in FIG. 2B.

FIG. 3A is another enlarged top view of the region 120 in accordance with the embodiment of FIG. 1.

FIG. 3B is an enlarged view of a scribe line structure 300 in FIG. 3A.

FIGS. 3C-3D are cross-sectional views of the semiconductor wafer 1 along line BB′ in FIG. 3B.

FIG. 4A is a top view 400A of the die region 110 after the dicing process in accordance with an embodiment of the present disclosure.

FIG. 4B is a cross-sectional view 400B along line CC′ in FIG. 4A.

FIG. 4C is a side view 400C of a semiconductor chip package in accordance with an embodiment of the present disclosure.

FIG. 5 is a flowchart of a method for fabricating a semiconductor chip in accordance with an embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (for example, rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

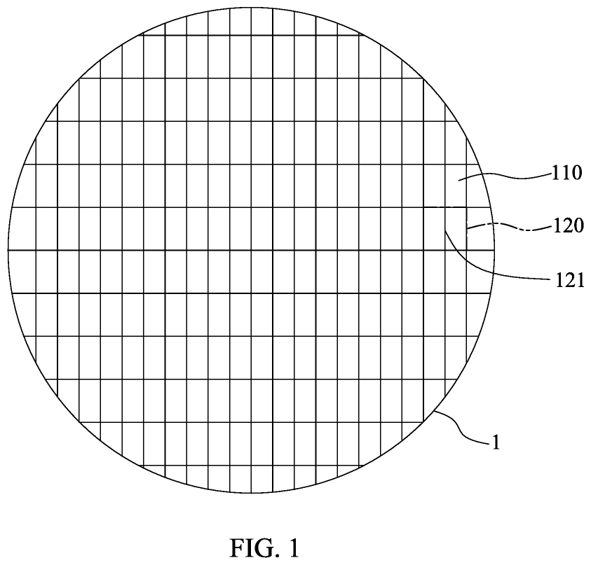

FIG. 1 is a top view of a semiconductor wafer 1 in accordance with some embodiments of the present disclosure.

As shown in FIG. 1, the semiconductor wafer 1 includes a plurality of die regions 110, each surrounded by a scribe line region 121, such that every two adjacent die regions 110 are separated by the scribe line region 121. The scribe line region 121 is a non-functional region on the semiconductor wafer 1. In addition, one or more dicing paths may be defined on the scribe line region 121. In some embodiments, the dicing path may be from top to bottom and from left to right, or from bottom to top and from right to left, depending on the dicing equipment.

Specifically, a semiconductor chip or die (such as an image sensor chip) is typically fabricated on a single semiconductor wafer along with hundreds, and in some cases thousands, of copies of the same die. The cutting needed to separate individual dies from a semiconductor wafer, a process known as “dicing” or “wafer dicing”, can be performed with a die saw (such as a diamond saw). Cuts are made along non-functional regions of semiconductor material, known as scribe lines (i.e., scribe line region 121), that separate the die regions 110 on the semiconductor wafer 1.

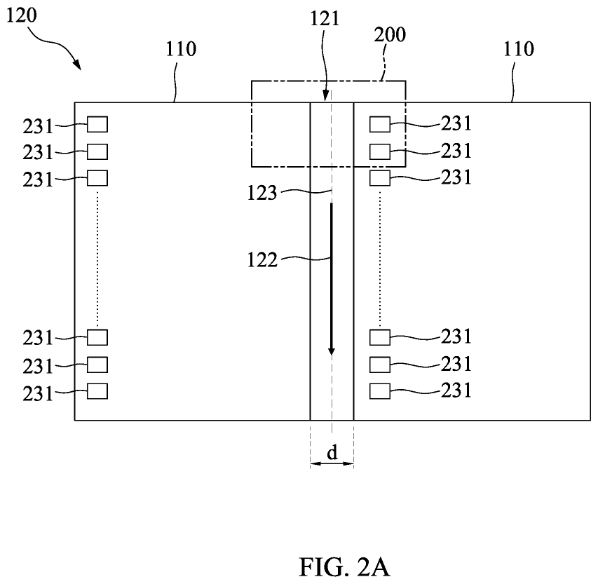

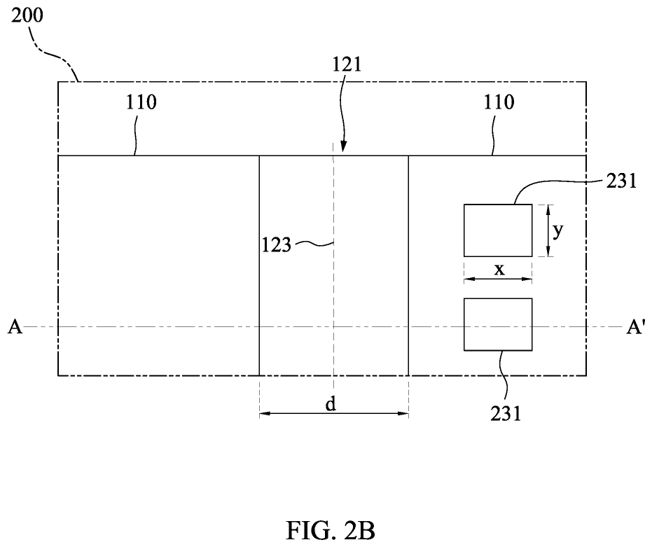

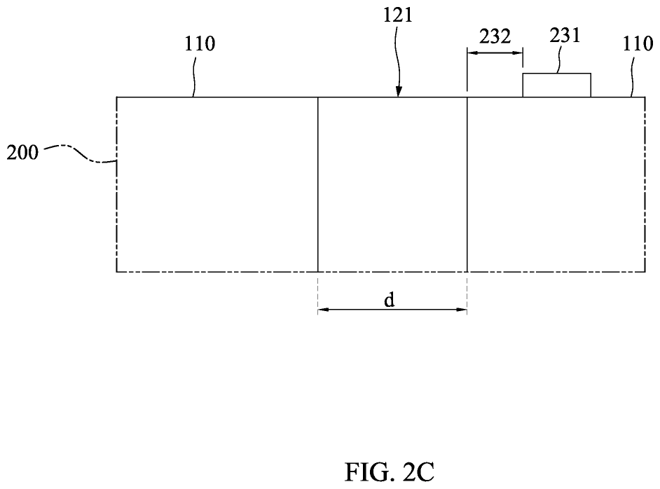

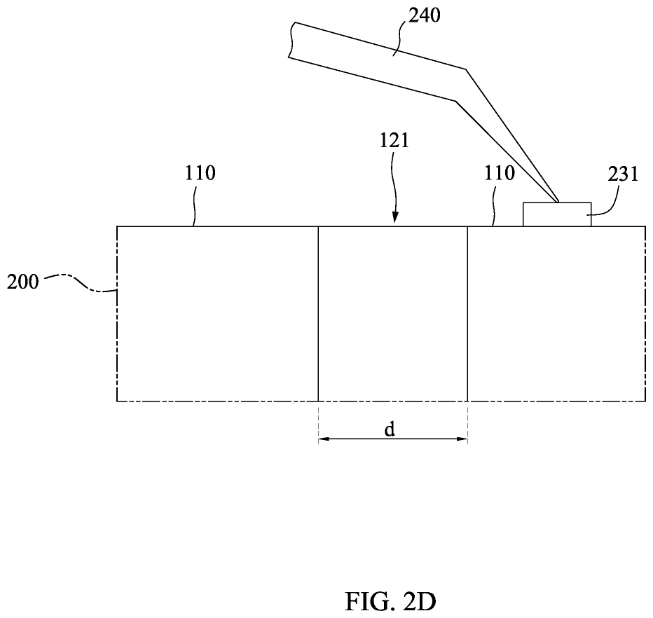

FIG. 2A is an enlarged top view of region 120 in accordance with the embodiment of FIG. 1. Please refer to FIG. 1 and FIG. 2A.

The enlarged top view of region 120 in FIG. 1 is shown in FIG. 2A. For example, there are two semiconductor chips (or dies) 110 in region 120. These two die regions 110 are separated by a scribe line region 121, and a dicing path 122 is defined on the scribe line region 121. For purposes of description, the dicing path 122 may align with the center line 123 of the scribe line region 121. In addition, a plurality of circuit probing pads 231 are disposed on a top surface (not shown in FIG. 2A) of an edge region of each of these two die regions 110. For purposes of description, the circuit probing pads 231 are disposed on the left edge region of these two die regions 110, as shown in FIG. 2A.

In some embodiments, functional circuitry may be located under the plurality of circuit probing pads 231, so each die region 110 can be tested through one or more circuit probing needles (not shown in FIG. 2A) electrically connected to external testing equipment and placed on the plurality of circuit probing pads 231 during manufacture or testing of the die regions 110. In some embodiments, the width d of the scribe line region 121 may range from 80 to 100 μm, but the present disclosure is not limited thereto.

FIG. 2B is an enlarged view of scribe line structure 200 in FIG. 2A. In some embodiments, the size of each circuit probing pad 231 may be x μm*y μm, where the values of x and y may be 68 and 60, respectively, but the disclosure is not limited thereto. Thus, the size of each circuit probing pad 231 is sufficient to accommodate a circuit probing needle thereon.

FIGS. 2C-2D are cross-sectional views of the semiconductor wafer 1 along line AA′ in FIG. 2B. Please refer to FIGS. 2B-2D.

As shown in FIG. 2C, the circuit probing pad 231 is disposed on the top surface of the left edge region of each die region 110. It should be noted that a margin 232 between the circuit probing pad 231 and the scribe line region 121 ensures that the circuit probing pad 231 will not be diced out from the semiconductor wafer 1 along with the scribe line region 121.

In some embodiments, after the circuit probing pads 231 are formed on the top surface of the left edge region of each die region 110, the functional circuitry of each die region 110 can be tested via one or more circuit probing needles 240 electrically connected to external testing equipment and placed on each circuit probing pad 231, as shown in FIG. 2D. After the functional circuitry of each die region 110 on the semiconductor wafer 1 has been tested, a copper pillar bump (not shown) may be formed on each circuit probing pad 231, to connect the die region 110 to a substrate of a printed circuit board (not shown) using flip-chip packaging. In some other embodiments, the copper pillar bump (not shown) can be formed on each circuit probing pad 231 before testing the functional circuitry of each die region 110 via one or more circuit probing needles 240.

In yet some other embodiments, each die region 110 can be connected to a substrate of a printed circuit board (not shown) via wire bonding with the die region 110 facing up.

In the embodiments of FIGS. 2A to 2D, for purposes of description, the die region 110 may be a 2 Gb DDR4 die, for example. For example, the size of the 2 Gb DDR4 die may have an area of 2000 μm*4000 μm, and the chip size of the 2 Gb DDR4 die is approximately 8 mm². In addition, the circuit probing pad 231 (or the bonding pad) may have a size of 60 μm*68 μm, which is approximately equal to 0.00408 mm². In addition, a total number of the circuit probing pads 231 is about 200 for one die region 110, the total area of the circuit probing pads 231 is approximately 0.00408 mm²*200=0.816 mm². Accordingly, the circuit probing pads 231 may occupy 10.2% (i.e., 0.816/8=10.2%) of the overall area of the die region 110.

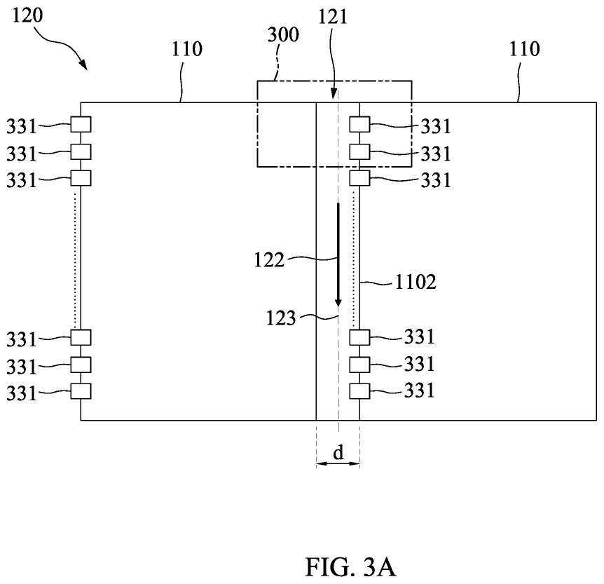

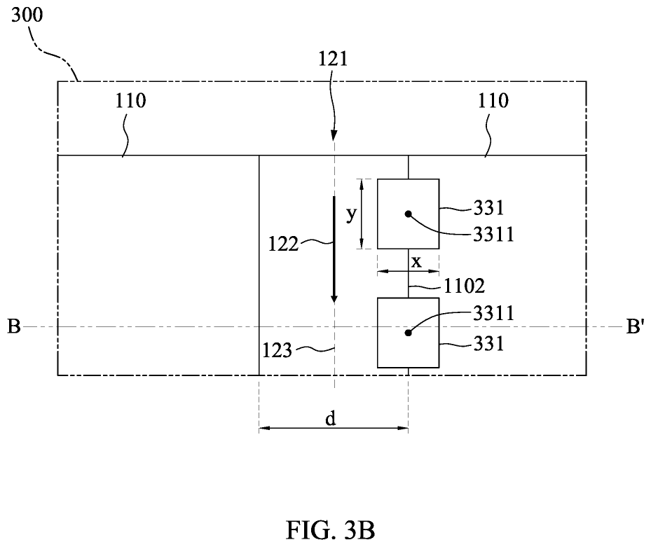

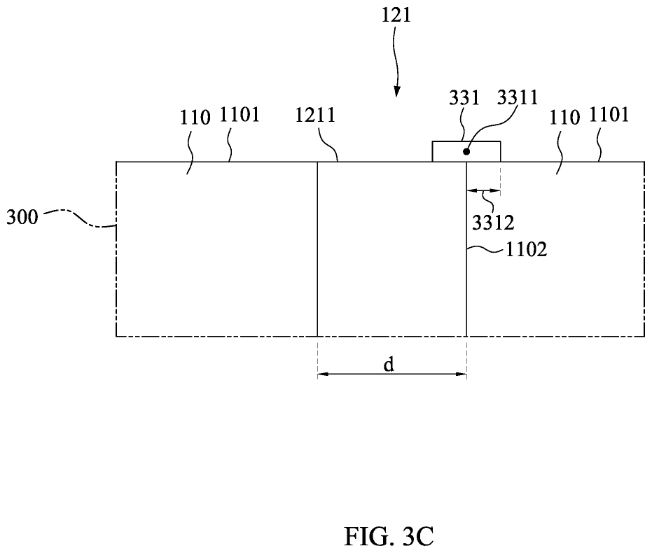

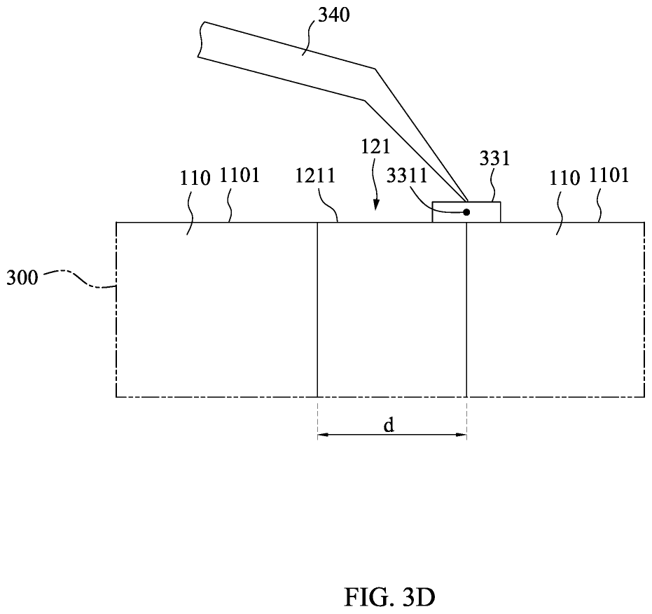

FIG. 3A is another enlarged top view of region 120 in accordance with the embodiment of FIG. 1. Please refer to FIG. 1 and FIG. 3A.

Another enlarged top view of region 120 in FIG. 1 is shown in FIG. 3A. For example, there are two semiconductor chips (or dies) 110 in region 120. These two die regions 110 are separated by a scribe line region 121, and a dicing path 122 is defined on the scribe line region 121. In addition, a plurality of circuit probing pads 331 are disposed on a first top surface of the scribe line region 121 and a second top surface of the die region 110. In addition, the first top surface of the scribe line region 121 substantially aligns with the second top surface of the die region 110. In other words, the first top surface of the scribe line region 121 and the second top surface of the die region 110 are substantially coplanar.

For purposes of description, the plurality of circuit probing pads 331 are disposed on the left edge region of each die region 110. In some embodiments, a semiconductor chip package may have input/output pins on one or more edges thereof, and the plurality of circuit probing pads 331 may be disposed on two edge regions of each die region 110, such as two neighboring edge regions, or two opposite edge regions.

In some embodiments, there may be functional circuitry underneath the top surface of each die region 110 on which the circuit probing pads 331 are disposed, so each die region 110 can be tested through one or more circuit probing needles (not shown in FIG. 3A) electrically connected to external testing equipment and placed on the plurality of circuit probing pads 331 during manufacture or testing of the die regions 110.

In some embodiments, the width d of the scribe line region 121 between these two die regions 110 may range from 80 to 100 μm, but the present disclosure is not limited thereto.

FIG. 3B is an enlarged view of a scribe line structure 300 in FIG. 3A. In some embodiments, the size of each circuit probing pad 331 may be x μm*y μm, where the values of x and y may be 68 and 60, respectively. Thus, the size of each circuit probing pad 331 is sufficient to accommodate a circuit probing needle (not shown in FIG. 3B) thereon. In some embodiments, the center 3311 of each circuit probing pad 331 may be disposed on the left edge 1102 between the scribe line region 121 and the left edge 1102 of the die region 110 on the right. Thus, there is a safe margin 332 between the center line 123 of the scribe line region 121 and the left edge 1102 of the die region 110 on the right. Accordingly, when the semiconductor wafer 1 is diced on the scribe line region 121 to separate each die region 110, the die regions 110 will not be damaged.

In some other embodiments, the center 3311 of each circuit probing pad 331 may be located on the left (i.e., farther away from the die region 110) or right (i.e., closer to the die region 110) of the center line 123 of the scribe line region 121 depending on manufacture needs or design trade-offs. For example, when the center 3311 of each circuit probing pad 331 is located on the left of the center line 123 of the scribe line region 121, it indicates that the center 3311 of each circuit probing pad 331 is disposed away from the die region 110 with reference to a center line 123 of the scribe line region 121. In addition, when the center 3311 of each circuit probing pad 331 is located on the right of the center line 123 of the scribe line region 121, it indicates that the center 3311 of each circuit probing pad 331 is disposed closer to the die region 110 with reference to a center line 123 of the scribe line region 121. In other words, the percentage of each circuit probing pad 331 disposed on the top surface of the scribe line region 121 can be alternated according to manufacture needs.

For example, when the center 3311 of each circuit probing pad 331 is located on the left of the center line 123 of the scribe line region 121, most of each circuit probing pad 331 is diced out from the semiconductor wafer 1 along with the scribe line region 121, but the contact area between each circuit probing pad 331 and the functional circuitry of the die region 110 is smaller. When the center 3311 of each circuit probing pad 331 is located on the right of the center line 123 of the scribe line region 121, part of each circuit probing circuit pad 331 is diced out from the semiconductor wafer 1 along with the scribe line region 121, but the contact area between each circuit probing pad 331 and the functional circuitry of the die region 110 is larger. Thus, the manufacturer can find an appropriate percentage of each circuit probing pad 331 to be disposed on the top surface of the scribe line region so as to reduce the overall area of each die region 110 (or the semiconductor package) and facilitating tests of the functional circuitry of each die region 110.

In some embodiments, when the center 3311 of each circuit probing pad 331 is located on the left of the center line 123 of the scribe line region 121, most of each circuit probing pad 331 will be diced out from the semiconductor wafer 1 together with a portion of the scribe line region 121 after testing the functional circuitry of the die region 110.

It should be noted that the top surfaces of the scribe line region 121 and the die regions 110 in FIG. 3B may be substantially level, and can be regarded as the common top surface of the semiconductor wafer 1.

FIGS. 3C-3D are cross-sectional views of the semiconductor wafer 1 along line BB′ in FIG. 3B. Please refer to FIGS. 3B-3D.

As shown in FIG. 3C, the circuit probing pad 331 is disposed on the top surface of scribe line region 121. It should be noted that there is a safe margin 332 between the center line 123 of the scribe line region 121 and the left edge of the die region 110 on the right. Accordingly, when the semiconductor wafer 1 is diced on the scribe line region to separate each die region 110, the die regions 110 will not be damaged.

In some embodiments, after the circuit probing pads 331 are formed on the top surface of the semiconductor wafer 1, the functional circuitry of each die region 110 can be tested via one or more circuit probing needles 340 electrically connected to external testing equipment and placed on each circuit probing pad 331, as shown in FIG. 3D.

In view of the embodiments of FIGS. 3A-3D, the scribe line structure can be built step by step. For example, the circuit probing pads 331 are formed on the top surface of the scribe line region 121. After testing the functional circuitry of each die region 110, a portion of the circuit probing pad 331 will be diced out from the semiconductor wafer 1 together with a portion of the scribe line region 121, so the size of the die region 110 (or the semiconductor chip package) can be significantly reduced.

In the embodiments of FIGS. 3A to 3D, for purposes of description, a 2 Gb LPDDR4 die is used as an example. For example, the size of the 2 Gb LPDDR4 die may be 2000 μm*4000 μm, and the chip size of the 2 Gb LPDDR4 die is approximately 8 mm². In addition, the circuit probing pad 331 may have a size of 60 μm*80 μm, which is approximately equal to 0.00408 mm². It should be noted that the circuit probing pads 331 are disposed on the common top surface between the scribe line region 121 and the die region 110, and a portion of the area of the circuit probing pads 331 will be counted into the overall area of the die region 110.

Assuming that half of each circuit probing pad 331 is diced out from the semiconductor wafer 1 during the dicing process, it indicates that another half of each circuit probing pad 331 may be still located on the top surface of each die region 110. Thus, 50% overall area of the circuit probing pads 331 can be reduced using the scribe line structure 300 described in the embodiments of FIGS. 3A-3D, and the overall area of each die region 119 can be reduced by 5% in comparison with the scribe line structure 200 in the embodiments of FIGS. 2A-2D. In other words, the scribe line structure 300 shown in FIGS. 3A-3D can reduce the overall area of the die region 110 (or the semiconductor package) significantly.

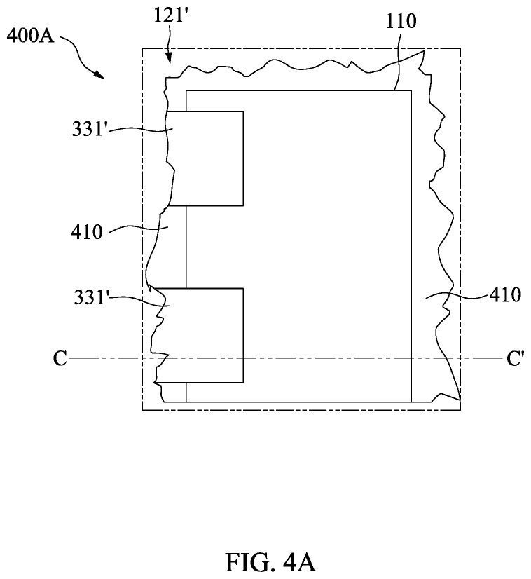

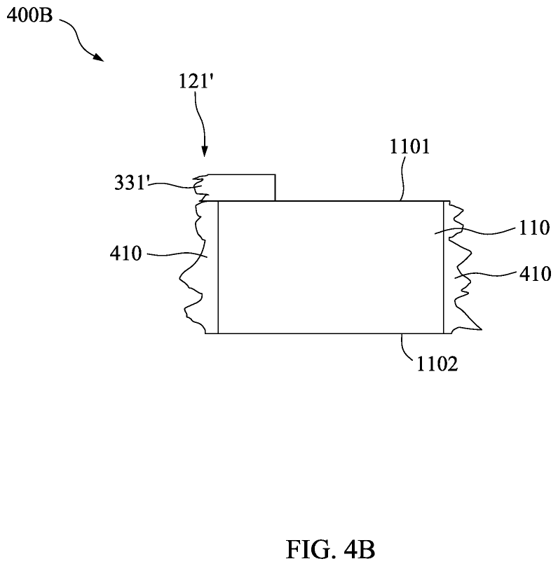

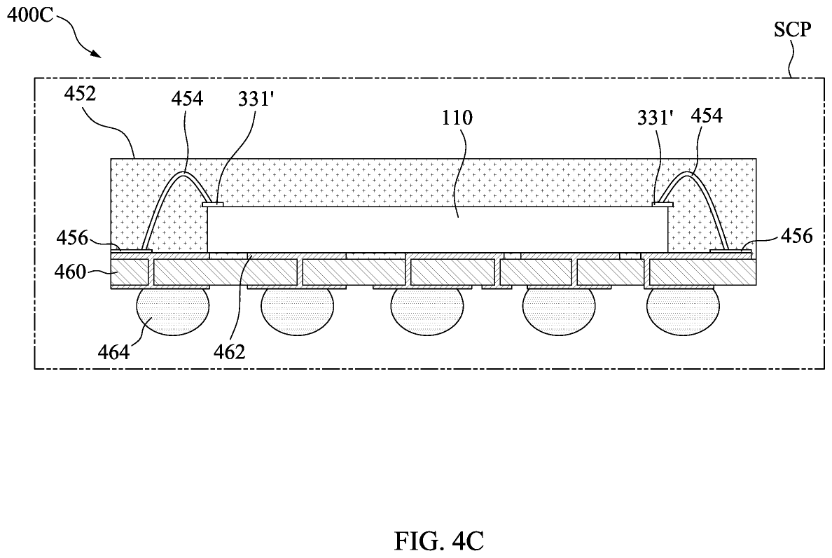

FIG. 4A is a top view 400A of the die region 110 after the dicing process in accordance with an embodiment of the present disclosure. FIG. 4B is a cross-sectional view 400B along line CC′ in FIG. 4A. FIG. 4C is a side view 400C of a semiconductor chip package in accordance with an embodiment of the present disclosure. Please refer to FIG. 3A and FIGS. 4A-4C.

After the scribe line region 121 in FIG. 3A is diced to separate the die regions 110, the top view of the diced die region 110 is shown in FIG. 4A. For example, the kerf regions 410 of the scribe line region 121 may not be level, a portion of the circuit probing pads 331 in FIG. 3A may be diced out from the semiconductor wafer 1. As shown in FIG. 4A, the kerf regions 410 surround the die region 110, the remaining circuit probing pad 331′ is still with the remaining scribe line region 121′ and the die region 110, as shown in FIG. 4B. Since the circuit probing pads 331 will no longer be used after the functional circuitry of the die regions 110 of the semiconductor wafer 1 has been tested, the circuit probing pads 331 can be cut off from the semiconductor wafer 1 together with the scribe line region 121.

Since the remaining circuit probing pads 331′ are still on the top surface of the die region 110, functional circuitry of the die region 110 will not be affected. Specifically, the components shown in FIG. 4B are part of overall components in the semiconductor chip package SCP, and die region 110 can be electrically connected to a substrate 460 of a printed circuit board (not shown) via wire bonding, as shown in FIG. 4C.

For example, the top surface 1101 of the die region 110 is facing upward, as shown in FIG. 4C. In addition, the functional circuitry of the die region 110 can be electrically connected from the remaining circuit probing pad 331′ (i.e., a remaining portion of the circuit probing pad 331) to the bond pad 456 disposed on metal connections 462 of the substrate 460 (e.g., a copper clad laminate, CCL) via metal wires 454, and the substrate 460 has one or more solder balls 464 disposed thereon. For example, the materials of the metal wires 454 may be one of aluminum, copper, silver, gold, alloyed aluminum, etc., but the present disclosure is not limited thereto. The die region 110 and metal wires 454 are encapsulated by the molding compound 452. In addition, the remaining circuit probing pads 331′ can be used as bonding pads that are electrically connected to the substrate 460 via the metal wires 454 in this embodiment.

Therefore, the components in the side view 400C in FIG. 4C can be packaged into a semiconductor chip package SCP, wherein the solder balls 464 can be regarded as the physical pads or pins of the semiconductor chip package SCP.

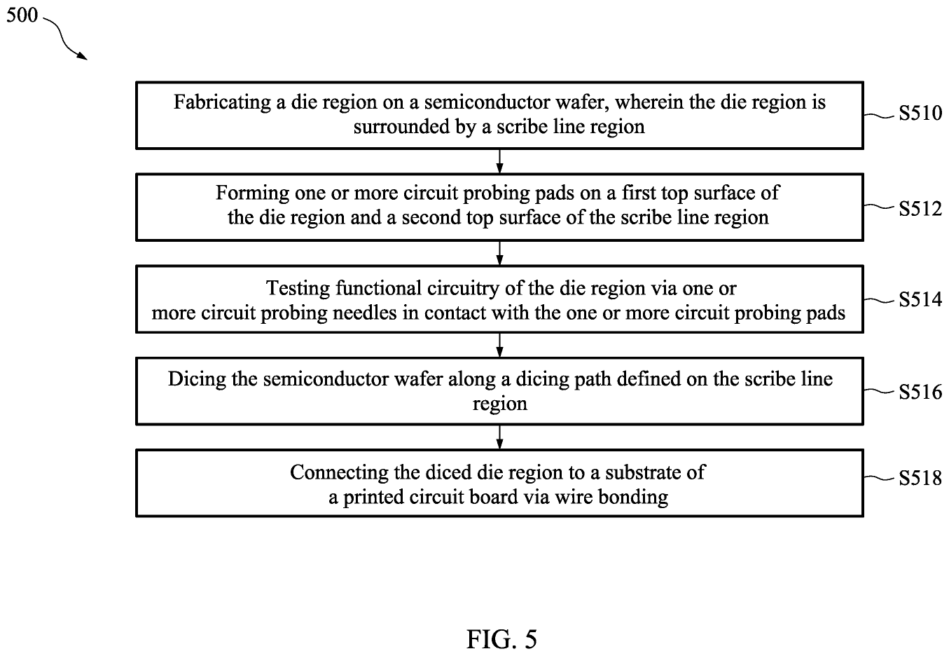

FIG. 5 is a flowchart of a method 500 for fabricating a semiconductor chip in accordance with an embodiment of the present disclosure. Please refer to FIG. 5 and FIGS. 3A-3D.

In step S510, a die region 110 is fabricated on a semiconductor wafer 1, wherein the die region 110 is surrounded by a scribe line region 121. For example, a single semiconductor wafer 1 may include hundreds or thousands of copies of the same die region 110. These die regions 110 on the semiconductor wafer 1 are separated by a “dicing” process on the scribe line region 121 of the semiconductor wafer 1, wherein each of the die regions 110 may include functional circuitry, and the scribe line region 121 may be a non-functional region.

In step S512, one or more circuit probing pads 331 are formed on a first top surface of the die region 110 and a second top surface of the scribe line region 121. In some embodiments, the size of each circuit probing pad 331 may be 60 μm*68 μm, but the present disclosure is not limited thereto. It should be noted that the first top surface of the die region 110 and the second top surface of the scribe line region 121 may be substantially level, and they can be regarded as the common top surface of the semiconductor wafer 1. In other words, the first top surface of the die region 110 and the second top surface of the scribe line region 121 are coplanar.

In step S514, functional circuitry of the die region 110 is tested via one or more circuit probing needles 340 in contact with the one or more circuit probing pads 331. For example, when the circuit probing needle 340, which is electrically connected to external test equipment, is placed on the one or more circuit probing pads 331, the functional circuitry of the die region 110 can be tested.

In step S516, the semiconductor wafer 1 is diced along a dicing path 122 defined on the scribe line region 121. For example, since the circuit probing pad 331 is formed on the top surface of the scribe line region 121, a portion of each circuit probing pad 331 will be diced out from the semiconductor wafer 1 together with a portion of the scribe line region 121 after testing the functional circuitry of the die region 110.

In step S518, the diced die region 110 is connected to a substrate 460 of a printed circuit board via wire bonding. For example, the functional circuitry of the die region 110 can be electrically connected from the remaining circuit probing pad 331′ to the bond pad 456 disposed on metal connections 462 of the substrate 460 (e.g., a copper clad laminate, CCL) via metal wires 454, and the substrate 460 has one or more solder balls 464 disposed thereon, as shown in FIG. 4C. For example, the materials of the metal wires 454 may be one of aluminum, copper, silver, gold, alloyed aluminum, etc., but the present disclosure is not limited thereto. The die region 110 and metal wires 454 are encapsulated by the molding compound 452.

In view of the embodiment in FIG. 5, a portion of the circuit probing pad 331 will be diced out from the semiconductor wafer 1 together with a portion of the scribe line region 121, so the size of the die region 110 (or the semiconductor chip package) can be significantly reduced.

The method 500 is merely an example, and is not intended to limit the present disclosure beyond what is explicitly recited in the claims. Additional operations can be provided before, during, or after each operation of the method 500, and some operations described can be replaced, eliminated, or reordered for additional embodiments of the method. In some embodiments, the method 500 can include further operations not depicted in FIG. 5.

One aspect of the present disclosure provides a scribe line structure. The scribe line structure includes a die region, a scribe line region, and one or more circuit probing pads. The die region is disposed on a semiconductor wafer. The scribe line region surrounds the die region. The one or more circuit probing pads are disposed on a first top surface of the die region and a second top surface of the scribe line region.

In some embodiments, the die region comprises functional circuitry, and the scribe line region is a non-functional region.

In some embodiments, a portion of each circuit probing pad is electrically connected to the functional circuitry of the die region.

In some embodiments, the functional circuitry of the die region is tested via one or more circuit probing needles electrically connected to external test equipment and placed on the one or more circuit probing pads.

In some embodiments, a center of each circuit probing pad is disposed on a boundary between the die region and the scribe line region.

In some other embodiments, a center of each circuit probing pad is disposed away from the die region with reference to a center line of the scribe line region.

In yet some other embodiments, a center of each circuit probing pad is disposed closer to the die region with reference to a center line of the scribe line region.

In some embodiments, a dicing process is performed on the semiconductor wafer along a dicing path defined on the scribe line region, and a portion of each circuit probing pad is diced from the semiconductor wafer.

In some embodiments, the die region and a remaining scribe-line structure are packaged into a semiconductor chip package.

In some embodiments, the semiconductor chip package further comprises a remaining circuit probing pad corresponding to each circuit probing pad obtained after the dicing process.

In some embodiments, the die region is electrically connected to a substrate of a printed circuit board via wire bonding.

In some embodiments, the first top surface of the die region and the second top surface of the scribe line region are coplanar.

Another aspect of the present disclosure provides a semiconductor device, which includes a plurality of die regions, a scribe line region, and a plurality of circuit probing pads. The plurality of die regions are disposed on a semiconductor wafer. The scribe line region is disposed between the plurality of die regions. The plurality of circuit probing pads are disposed on a first top surface of each die region and a second top surface of the scribe line region.

In some embodiments, each die region comprises functional circuitry, and the scribe line region is a non-functional region, the functional circuitry of each die region is tested via a plurality of circuit probing needles electrically connected to external test equipment and placed on the circuit probing pads.

In some embodiments, a center of each circuit probing pad is disposed on a boundary between each die region and the scribe line region.

In some other embodiments, a center of each circuit probing pad is disposed away from each die region with reference to a center line of the scribe line region.

In yet some other embodiments, a center of each circuit probing pad is disposed closer to each die region with reference to a center line of the scribe line region.

In some embodiments, a dicing process is performed on the semiconductor wafer along one or more dicing paths defined on the scribe line region, and a portion of each circuit probing pad is diced from the semiconductor wafer.

In some embodiments, the die region and a remaining scribe-line structure are packaged into a semiconductor chip package.

In some embodiments, the semiconductor chip package further comprises a remaining circuit probing pad corresponding to each circuit probing pad obtained after the dicing process.

In some embodiments, each die region is electrically connected to a substrate via wire bonding.

Yet another aspect of the present disclosure provides a method for fabricating a semiconductor chip. The method includes fabricating a die region on a semiconductor wafer, wherein the die region is surrounded by a scribe line region; and forming a circuit probing pad on a first top surface of the die region and a second top surface of the scribe line region.

In some embodiments, the die region comprises functional circuitry, and the scribe line region is a non-functional region.

In some embodiments, a portion of each circuit probing pad is electrically connected to the functional circuitry of the die region.

In some embodiments, after the step of forming a circuit probing pad on the first top surface of the die region and the second top surface of the scribe line region, the method further comprises: testing functional circuitry of the die region via a circuit probing needle electrically connected to external test equipment and placed on the circuit probing pad.

In some embodiments, a center of each circuit probing pad is disposed on a boundary between the die region and the scribe line region.

In some other embodiments, a center of each circuit probing pad is disposed away from the die region with reference to a center line of the scribe line region.

In yet some other embodiments, a center of each circuit probing pad is disposed closer to the die region with reference to a center line of the scribe line region.

In some embodiments, after the step of testing functional circuitry of the die region via a circuit probing needle electrically connected to external test equipment and placed on the circuit probing pad, the method further comprises performing a dicing process on the semiconductor wafer along a dicing path defined on the scribe line region.

In some embodiments, the method further includes: packaging the die region and a remaining scribe-line structure into a semiconductor chip package.

In some embodiments, the semiconductor chip package further comprises a remaining circuit probing pad corresponding to each circuit probing pad obtained after the dicing process.

In some embodiments, the die region is electrically connected to a substrate via wire bonding.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor device, comprising:
a plurality of die regions, disposed on a semiconductor wafer;
a scribe line region, disposed between the plurality of die regions; and
a plurality of circuit probing pads, disposed on a first top surface of each die region and a second top surface of the scribe line region.

2. The semiconductor device of claim 1, wherein each die region comprises functional circuitry, and the scribe line region is a non-functional region.

3. The semiconductor device of claim 2, wherein a portion of each circuit probing pad is electrically connected to the functional circuitry of each die region.

4. The semiconductor device of claim 3, wherein the functional circuitry of each die region is tested via a plurality of circuit probing needles electrically connected to external test equipment and placed on the one or more circuit probing pads.

5. The semiconductor device of claim 1, wherein a center of each circuit probing pad is disposed on a boundary between each die region and the scribe line region.

6. The semiconductor device of claim 1, wherein a center of each circuit probing pad is disposed away from each die region with reference to a center line of the scribe line region.

7. The semiconductor device of claim 1, wherein a center of each circuit probing pad is disposed closer to each die region with reference to a center line of the scribe line region.

8. The semiconductor device of claim 4, wherein a dicing process is performed on the semiconductor wafer along one or more dicing paths defined on the scribe line region, and a portion of each circuit probing pad is diced from the semiconductor wafer.

9. The semiconductor device of claim 8, wherein the die region and a remaining scribe-line structure are packaged into a semiconductor chip package.

10. The semiconductor device of claim 9, wherein the semiconductor chip package further comprises a remaining circuit probing pad corresponding to each circuit probing pad obtained after the dicing process.

11. The semiconductor device of claim 7, wherein each die region is electrically connected to a substrate via wire bonding.
